(19) United States
(12) Patent Application Publication
(10) Pub. No.: US 2023/0153482 A1
(43) Pub. Date: May 18, 2023

(54) METHOD FOR DESIGNING RECEIVER COIL BASED ON ARBITRARY TARGET SHAPE

(71) Applicant: Renesas Electronics America Inc., Milpitas, CA (US)

(72) Inventors: Gentjan Qama, Munich (DE); Jon Zeynel Tuna, Laguna Hills, CA (US)

(73) Assignee: Renesas Electronics America Inc., Milpitas, CA (US)

(21) Appl. No.: 17/525,399

(22) Filed: Nov. 12, 2021

(51) Int. Cl. G06F 30/17; G01D 5/20

(52) U.S. Cl. CPC G06F 30/17; G01D 5/204

(57) ABSTRACT

Systems and methods for designing receiving coils of an inductive position sensor are described. A processor may receive input data indicating a shape of a target of the inductive position sensor. The processor may identify an overlapping region between the target and a transmitting coil of the inductive position sensor. The processor may determine a shape of a receiving coil cell based on the identified overlapping region. The processor may generate a model of the receiving coils of the inductive position sensor based on the shape of the receiving coil cell.

### TECHNICAL FIELD

The present disclosure relates generally to systems and methods for inductive position sensing devices, and more particularly, to methods for designing receiver coils based on a target shape.

### BACKGROUND

Unless otherwise indicated herein, the materials described in this section are not prior art to the claims in this application and are not admitted to be prior art by inclusion in this section.

An inductive position sensor can include a transmitting coil and a pair of receiving coils printed on a printed circuit board (PCB). The inductive position sensor can further include an integrated circuit (IC) configured to drive the transmitting coil to generate an alternating magnetic field with the pair of receiving coils. A target (e.g., an object having magnetic properties) can be located in proximity to the transmitting coil and the pair of receiving coils. For example, the target can be placed above or below the PCB (e.g., a plane where the transmitting coil and the pair of receiving coils are printed). The magnetic field generated by the transmitting coil can induce eddy currents on the target, and the eddy current can generate a counter magnetic field, changing (e.g., reducing) a magnetic flux density between the target and the pair of receiving coils. The changes to the magnetic flux density between the target and the pair of receiving coils can generate a voltage at terminals of the pair of receiving coils. The IC can measure the generated voltages and the measurements can be used for determining a position of the target with respect to the transmitting and the pair of receiving coils.

### SUMMARY

In one embodiment, a method for designing receiving coils of an inductive position sensor is generally described. The method may include receiving input data indicating a shape of a target of the inductive position sensor. The method may further include identifying an overlapping region between the target and a transmitting coil of the inductive position sensor. The method may further include determining a shape of a receiving coil cell based on the identified overlapping region. The method may further include generating a model of the receiving coils of the inductive position sensor based on the shape of the receiving coil cell.

In an example, a method for designing receiving coils of an inductive position sensor is generally described. The system may include a memory configured to store a set of instructions. The system may further include a processor configured to be in communication with the memory. The processor may be configured to execute the set of instructions to receive input data indicating a shape of a target of an inductive position sensor. The processor may be further configured to identify an overlapping region between the target and a transmitting coil of the inductive position sensor. The processor may be further configured to determine a shape of a receiving coil cell based on the identified overlapping region. The processor may be further configured to generate a model of receiving coils of the inductive position sensor based on the shape of the receiving coil cell.

In an example, a computer program product for designing receiving coils of an inductive position sensor is generally described. The computer program product may include a computer readable storage medium having program instructions executable by a processor to receive input data indicating a shape of a target of the inductive position sensor. The program instructions may be further executable by the processor identify an overlapping region between the target and a transmitting coil of the inductive position sensor. The program instructions may be further executable by the processor determine a shape of a receiving coil cell based on the identified overlapping region. The program instructions may be further executable by the processor generate a model of the receiving coils of the inductive position sensor based on the shape of the receiving coil cell.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 is a diagram illustrating an example system that may implement receiver coil design based on arbitrary target shape in one embodiment.

FIG. 2 is a diagram illustrating an example model that can be used for designing receiving coils of an inductive position sensor in one embodiment.

FIG. 3A is a diagram illustrating an example model of a transmitting coil and a pair of receiving coils generated by an implementation of the example system 100 of FIG. 1 in one embodiment.

FIG. 3B is a diagram illustrating the example model shown in FIG. 3A with a model of a target in one embodiment.

FIG. 4 is a diagram illustrating another example receiving coil generated by an implantation of the example system 100 of FIG. 1 in one embodiment.

FIG. 5 is a flowchart of an example process 500 that may implement receiver coil design based on arbitrary target shape in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

In an aspect, a pattern and/or shape of the receiving coils can be designed such that the voltages induced on the receiving coils can have sinusoidal waveforms. For example, the receiving coils can include a first receiving coil and a second receiving coil printed on a printed circuit board (PCB) as a pair of out-of-phase sinusoidal wave forms (e.g., resembling a sine wave and a cosine wave). The overlapping geometry of the pair of receiving coils can form one or more loops (e.g., closed loops) on the PCB. If the target covers an entirety of a loop on the PCB, the voltages induced on the first coil and the second coil can cancel each other. The cancellation of the voltages in response to the target covering a loop entirely can allows the voltages measured by the IC to have periodic waveforms as the target moves or sweeps across the PCB. The periodic waveforms can represent a function of the target's position.

In an aspect, the geometry of the receiving coils can restrict a size and/or shape of the target because it may be desirable to have the target cover loops of the overlapping portions of the receiving coils entirely. If a target's shape is irregular, or too small, to cover the loops entirely, then the waveforms of the measured voltage can become unstable and it may be difficult to model a function of the target's positions. The methods and systems described herein can allow the receiving coils to be designed based on any arbitrary size and/or shape of a target. The designed receiving coils can allow the target (that was used for the receiving coil design) to cover overlapping loops of the receiving coils entirely and can allow a function of the target's positions to be modeled as periodic waveforms.

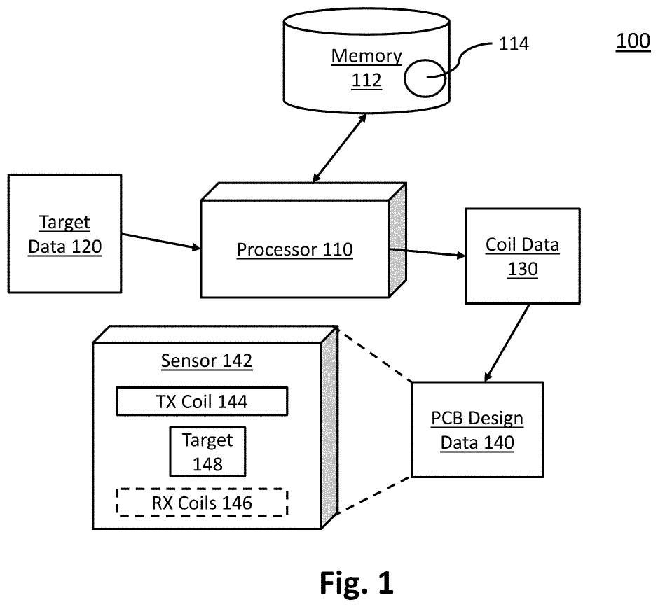

FIG. 1 is a diagram illustrating an example system 100 that may implement receiver coil design based on arbitrary target shape in one embodiment. The system 100 can be a computing system being implemented in a computing device such as a desktop computer, a laptop computer, a tablet device, a server, and/or other types of computing devices. The system 100 can include a processor 110 and a memory 112 configured to be in communication with one another. The processor 110 can be, for example, a microprocessor or a central processing unit (CPU) of a computer device. The memory 112 can be a memory device including one or more volatile and/or non-volatile memory units. In one or more embodiments, the memory 112 can be configured to store a set of instructions 114. The set of instructions 114 can include program code, such as source code and/or executable code, that can be executed by the processor 110 to perform one or more tasks and/or functions of the methods described herein. In one embodiment, the set of instructions 114 can be source code and/or executable code of an electronic design automation (EDA) tool. The processor 110 can be configured to execute the set of instructions 114 to run the EDA tool to design and simulate electronic circuits, such as designing geometry of transmitting coil and receiving coils of an inductive position sensor and simulating operations of the inductive position sensor.

In one or more embodiments, the processor 110 can be configured to receive input data, such as target data 120, from another processor or device. The target data 120 can be, for example, data indicating one or more geometric attributes of a target 148 of an inductive position sensor 142 (“sensor 142”). In one embodiment, the target 148 can be composed by materials having magnetic properties, such as ferrite or other materials that have magnetic properties. The one or more geometric attributes indicated by the target data 120 can include, for example, a shape, size (e.g., length, width, thickness), weight, position within the inductive position sensor 142, etc., of the target 148. In one embodiment, the target data 120 can be stored in the memory 112, and the processor 110 can be configured to retrieve the target data 120 from the memory 112. In another embodiment, the processor 110 can receive a user request 118, where the user request 118 is for designing or creating receiving coils 146 (“RX coils 146”) of the inductive position sensor 142 based on the target data 120. In response to receiving the user request 118, the processor 110 can retrieve the target data 120 from the memory 112.

In one or more embodiments, geometric attributes of the target 148 (e.g., size, shape, etc.), and geometric attributes of a transmitter coil 144 (“TX coil 144”) of the sensor 142 (e.g., size, shape, pattern, etc.) can be known and/or stored in the memory 112. The processor 110 can be configured to execute the set of instructions 114 to determine geometric attributes of the RX coils 146 of the sensor 142 based on attributes of the target 148 and/or the TX coil 144. For example, the processor 110 can determine a size, a shape, a pattern, etc., of the RX coils 146. In response to determining the geometric attributes of the RX coils 146, the processor 110 can generate printed circuit board (PCB) design data 140 using the geometric attributes of the TX coil 144, the RX coils 146, and the target 148. The processor 110 can be further configured to store the PCB design data 140 in the memory 112.

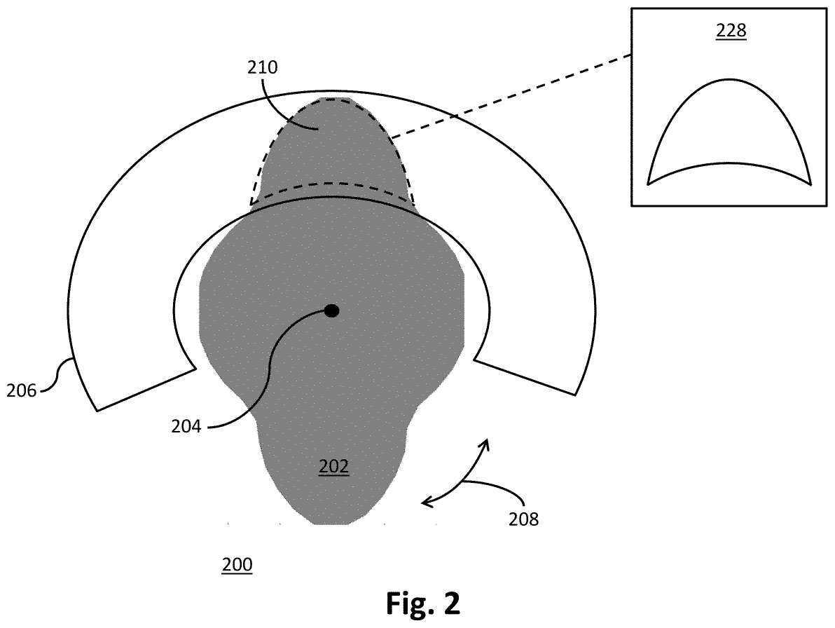

FIG. 2 is a diagram illustrating an example model 200 that can be used for designing receiving coils of an inductive position sensor in one embodiment. In the example shown in FIG. 2, the sensor 142 (see FIG. 1) can be an inductive angular position sensor and the geometry attributes of the TX coil 144 (see FIG. 1) can be predefined. The processor 110 (see FIG. 1) can be configured to generate a model 206 of the TX coil 144 based on the predefined geometry attributes. In another embodiment, the model 206 can be stored in the memory 112 and the processor 110 can be configured to retrieve the model 206 from the memory 112. In one embodiment, the model 206 can be a two dimensional (2D) image or a three dimensional (3D) image of the TX coil 144. In response to receiving the target data 120 (see FIG. 1), the processor 110 can generate a model 202 of the target 148 (see FIG. 1). In one embodiment, the model 202 can be a 2D or a 3D image of the target 148.

The processor 110 can be further configured to combine the models 202, 206 to generate a model 200. In one embodiment, the model 200 can be a 2D or a 3D image of the sensor 142 (see FIG. 1). In one embodiment, the processor 110 can combine the models 202, 206 by positioning the models 202, 206 in positions in accordance with a design specification of the sensor 142, where the design specification of the sensor 142 can be stored in the memory 112. In one embodiment, the sensor 142 can be an inductive angular position sensor and a portion of the target 148 can overlap with one or more portions of the TX coil 144. For example, as shown by the model 200, the models 202, 206 can overlap at a region 210. The processor 110 can determine a shape, size, and/or dimensions of the RX coils 146 based on the region 210. For example, the processor 110 can set a pattern, or a shape of a portion, labeled as a cell 228, of the RX coils 146 to be identical to the shape of the region 210. In one embodiment, the processor 110 can generate the cell 228 as a 2D or a 3D image data. To be described in more detail below, the processor 110 can be configured to simulate operations of the sensor 142 by rotating the model 202 of the target 148 in directions 208 about a pivot point 204.

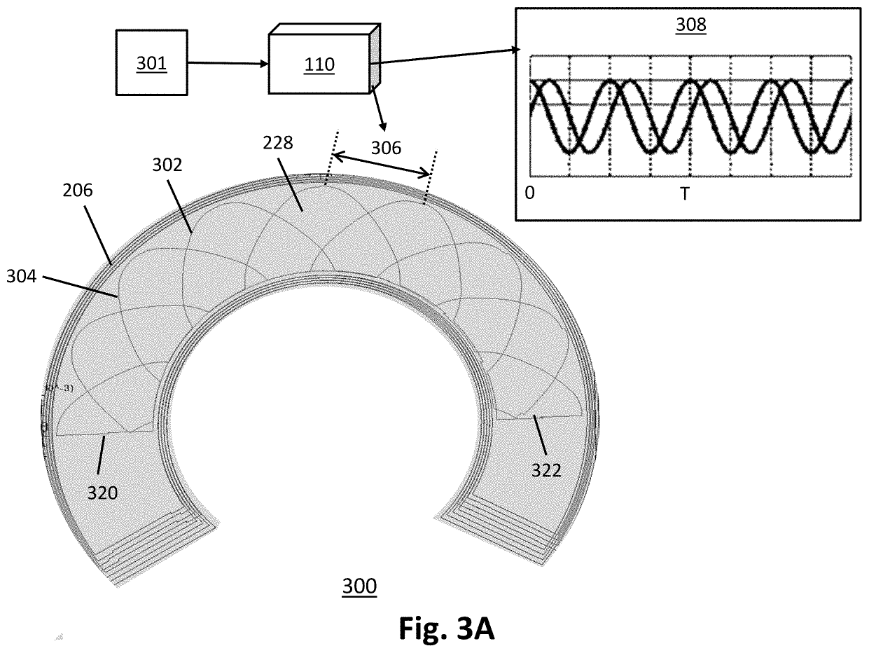

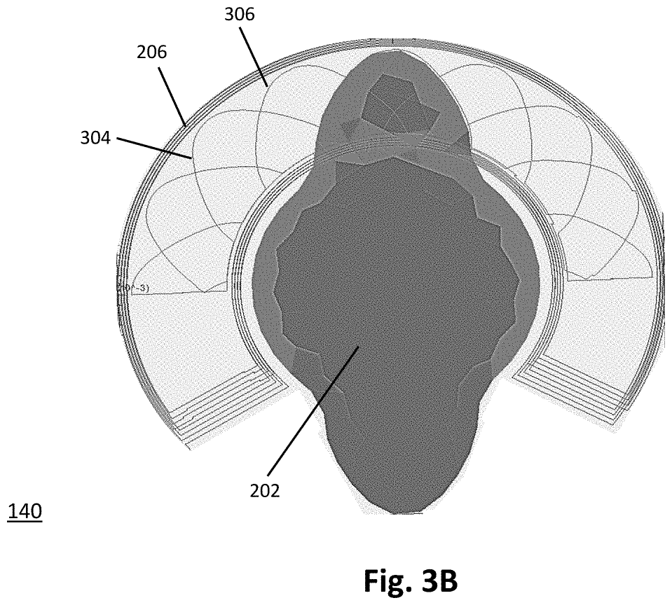

FIG. 3A is a diagram illustrating an example model of a transmitting coil and a pair of receiving coils generated by an implementation of the example system 100 of FIG. 1 in one embodiment. In one embodiment, the processor 110 can generate a model 300 including the model 206 of the TX coil 144 (see FIG. 1), a first model 302 of a first coil of the RX coils 146 (see FIG. 1), and a second model 304 of a second coil of the RX coils 146. The processor 110 can receive specification data 301 of the sensor 142 (see FIG. 1) to determine a number of cells 228 (see FIG. 2) to be distributed within boundaries of the model 206 of the TX coil 144 (see FIG. 1) or the model 206 (see FIG. 2), and to determine a spacing 306 between the cells 228. The specification data 301 can indicate various attributes of the sensor 142 such as a target length, where the target length can be a length in which a target can travel end-to-end from one end 320 to another end 322. The specification data 301 can further include attributes such as a full turn movement value indicating an amount of rotation from the end 320 to the end 322 (e.g., 180 degrees). In one embodiment, the full turn movement value can be equivalent to a period T of waveforms 308 representing the voltages induced on the RX coils 146 (see FIG. 1). In one embodiment, the benchmark waveform can represent desired voltages as a function of a plurality of positions of the target.

In one embodiment, the processor 110 can receive the specification data 301, and generate the waveform 308 as a benchmark waveform to determine the spacing 306. For example, the processor 110 can generate the model 300 to have a candidate spacing value between the cells 228. The processor 110 can simulate operations of the sensor 142 by moving or rotating the model 202 of the target (see FIG. 2) from the end 320 to the end 322 (e.g., sweeping the target across all possible target positions). The processor 110 can record the voltages being induced on the RX coils 146 and generate a candidate waveform representing the recorded voltages. The processor 110 can compare the candidate waveform with the benchmark waveform (e.g., waveform 308) to determine whether there is any difference between the candidate waveform and the waveform 308.

In response to a determination that there is no difference between the candidate waveform and the waveform 308, the processor 110 can set the candidate spacing as the spacing 306 of the RX coils 146. In response to a determination that there is a difference between the candidate waveform and the waveform 308, such as different amplitude and/or phase, the processor 110 can adjust the candidate spacing (e.g., increase or decrease) and repeat the simulation. The processor 110 can repeat the simulation using different candidate spacing until a desired spacing is identified.

Based on the determined spacing (e.g., spacing 306), the processor 110 can generate the model 300. The processor 110 can compile geometric attributes of the RX coils 146, such as the pattern and/or shape of the cell 228, the number of cells 228 in the model 300, the spacing 306, and/or other geometric attributes of the RX coils 146. The processor 110 can generate the PCB design data 140 (see FIG. 1) shown in FIG. 3B. The PCB design data 140 can include the model 206 of the TX coil 144, the models 302, 304 of the RX coils 146, and the model 202 of the target 148. The processor 110 can provide the PCB design data 140 to an apparatus configured to implement an EDA tool to print the TX coil 144 and the RX coils 146 on a PCB according to the PCB design data 140. In one embodiment, the system 100 can be within the apparatus configured to implement the EDA tool to print the TX coil 144 and the RX coils 146 on a PCB.

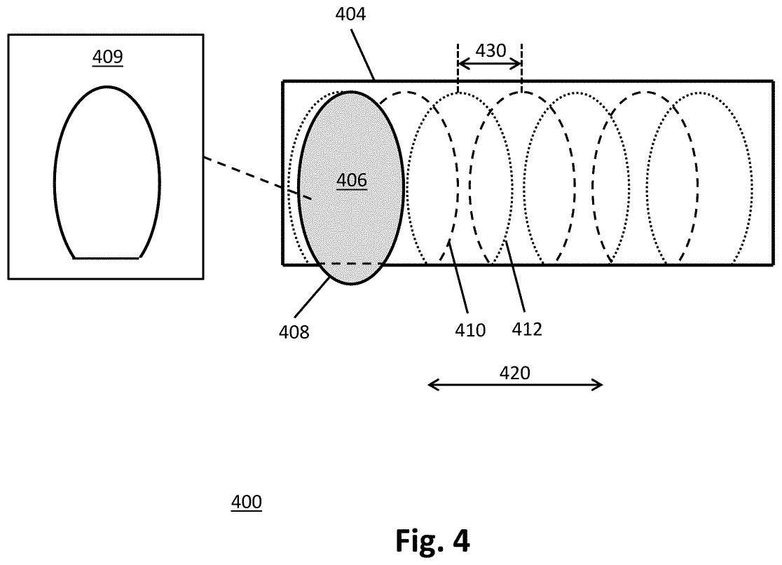

FIG. 4 is a diagram illustrating another example receiving coil generated by an implantation of the example system 100 of FIG. 1 in one embodiment. In the example shown in FIG. 4, the sensor 142 (see FIG. 1) can be a linear inductive position sensor and the geometry attributes of the TX coil 144 (see FIG. 1) can be predefined. The processor 110 (see FIG. 1) can be configured to generate a model 404 of the TX coil 144 based on the predefined geometry attributes. In another embodiment, the model 404 can be stored in the memory 112 and the processor 110 can be configured to retrieve the model 404 from the memory 112. In one embodiment, the model 404 can be a two dimensional image (2D) or a three dimensional (3D) image of the TX coil 144. In response to receiving the target data 120 (see FIG. 1), the processor 110 can generate a model 408 of the target 148 (see FIG. 1). In one embodiment, the model 408 can be a 2D or a 3D image of the target 148.

The processor 110 can be further configured to combine the models 404, 408 to generate a model 400. In one embodiment, the model 400 can be a 2D or a 3D image of the sensor 142 (see FIG. 1). In one embodiment, the processor 110 can combine the models 404, 408 by positioning the models 404, 408 in positions in accordance with a design specification of the sensor 142, where the design specification of the sensor 142 can be stored in the memory 112. In the example shown in FIG. 4, the models 404, 408 can overlap at a region 406. The processor 110 can determine a shape, size, and/or dimensions of the RX coils 146 based on the region 406. For example, the processor 110 can set a shape of a portion, such as a cell 409, of the RX coils 146 to be identical to the shape of the region 406. The processor 110 can be configured to simulate operations of the sensor 142 by linearly moving the model 408 of the target 148 in directions 420.

The processor 110 can add a first model 410 of a first coil of the RX coils 146 (see FIG. 1), and a second model 412 of a second coil of the RX coils 146, to the model 400. The processor 110 can receive specification data of the sensor 142 (see FIG. 1) to determine a number of cells 409 to be distributed within boundaries of the model 404 of the TX coil 144, and to determine a spacing 430 between the cells 409. The processor 110 can receive specification data and generate a benchmark waveform to determine the spacing 430. For example, the processor 110 can generate the model 400 to have a candidate spacing value between the cells 409 and simulate operations of the sensor 142 by moving the model 408 along the directions 420 to sweep the target across all possible target positions. The processor 110 can record the voltages being induced on the models 410, 412 and generate a candidate waveform representing the recorded voltages. The processor 110 can compare the candidate waveform with the benchmark waveform to determine whether there is any difference between the candidate waveform and the benchmark waveform. In response to a determination that there is no difference between the candidate waveform and the benchmark waveform, the processor 110 can set the candidate spacing as the spacing 430 of the RX coils 146. In response to a determination that there is a difference between the candidate waveform and the benchmark waveform, such as different amplitude and/or phase, the processor 110 can adjust the candidate spacing (e.g., increase or decrease) and repeat the simulation. The processor 110 can repeat the simulation using different candidate spacing until a desired spacing is identified.

Based on the determined spacing 430, the processor 110 can generate the model 400. The processor 110 can compile geometric attributes of the RX coils 146, such as the pattern and/or shape of the cell 409, the number of cells 409 in the model 400, the spacing 430, and/or other geometric attributes of the RX coils 146. The processor 110 can generate the PCB design data 140 (see FIG. 1) that includes the model 404 of the TX coil 144, the models 410, 412 of the RX coils 146, and the model 408 of the target 148. The processor 110 can provide the PCB design data 140 to an apparatus configured to implement an EDA tool to print the TX coil 144 and the RX coils 146 on a PCB according to the PCB design data 140.

The methods and systems described herein can allow the receiving coils of an inductive position sensor to be designed based on any arbitrary size and/or shape of a target. For example, the design of the receiving coils can be based on an overlapping region between the target and the transmitting coil of the inductive position sensor. By designing the receiving coils to match with the overlapping region, the designed receiving coils can allow the target to cover overlapping loops of the receiving coils entirely (e.g., cells 228, 409 in FIGS. 2 and 4, respectively) and can allow a function of the target's positions to be modeled as periodic waveforms. Devices and applications that utilize inductive position sensors can benefit from receiving coils designed based on arbitrary target shapes. For example, smaller targets can be used in the inductive position sensor since the loops of the receiving coils are designed to match the shape of the target.

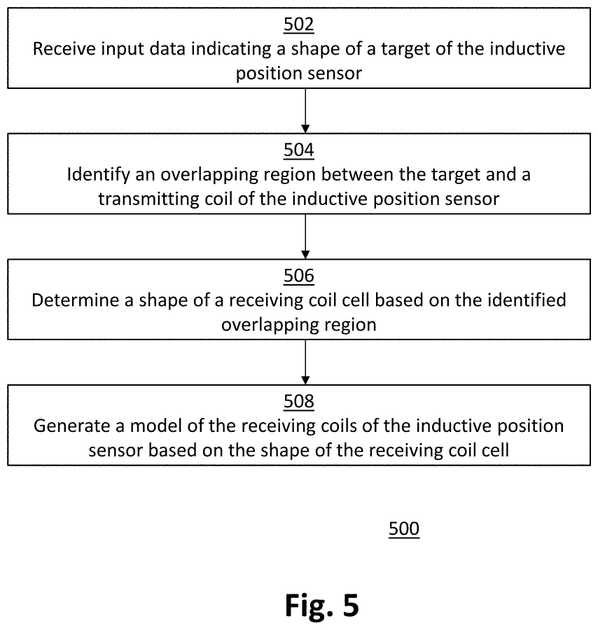

FIG. 5 is a flowchart of an example process 500 that may implement receiver coil design based on arbitrary target shape in one embodiment. The process 500 may include one or more operations, actions, or functions as illustrated by one or more of blocks 502, 504, 506, and/or 508. Although illustrated as discrete blocks, various blocks can be divided into additional blocks, combined into fewer blocks, eliminated, performed in parallel, and/or performed in a different order, depending on the desired implementation.

The process 500 may be implemented for designing receiving coils of an inductive position sensor. The process 500 may begin at block 502. At block 502, a processor may receive input data indicating a shape of a target of the inductive position sensor. In one embodiment, the processor may generate a model of the target based on the input data.

The process 500 may proceed from block 502 to block 504. At block 504, the processor may identify an overlapping region between the target and a transmitting coil of the inductive position sensor. In one embodiment, the processor may identify the overlapping region by combining a model of the target and a model of the transmitting coil based on specification data of the inductive position sensor.

The process 500 may proceed from block 504 to block 506. At block 506, the processor may determine a shape of a receiving coil cell based on the identified overlapping region. In one embodiment, the shape of the receiving coil cell may be the same as a shape of the overlapping region.

In one embodiment, the processor may determine a number of the receiving coil cells to be included in the model of the receiving coils. In one embodiment, the processor may determine a spacing between the number of the receiving coil cells. In one embodiment, the processor may receive a benchmark waveform representing voltages as a function of a plurality of positions of the target. The processor may generate a candidate model of the receiving coils, where the candidate model may include a plurality of the receiving coil cells arranged with a candidate spacing between one another. The processor may simulate a movement of the target in the inductive position sensor with the candidate model. The processor may record voltages generated from the simulated movement of the target. The processor may compare the recorded voltages with the benchmark voltages. The processor may generate the model of the receiving coils based on the comparison between the recorded voltages with the benchmark voltages.

In one embodiment, in response to the recorded voltages being the same as the benchmark voltages, the processor may set the candidate spacing as a final spacing between the plurality of the receiving coil cells in the model of the receiving coils. In response to the recorded voltages being different from the benchmark voltages, the processor may adjust the candidate spacing to generate a new candidate model and simulate a movement of the target in the inductive position sensor with the new candidate model. The processor may record new voltages generated from the simulated movement of the target in the inductive position sensor with the new candidate model. The processor may compare the recorded new voltages with the benchmark voltages. The processor may generate the model of the receiving coils based on the comparison between the recorded new voltages with the benchmark voltages.

The process 500 may proceed from block 506 to block 508. At block 508, the processor may generate a model of the receiving coils of the inductive position sensor based on the shape of the receiving coil cell. In one embodiment, the processor may generate printed circuit board (PCB) design data including the model of receiving coils and a model of the transmitting coil. The processor may send the PCB design data to an apparatus configured to print the receiving coils and the transmitting coil on a PCB.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. For example, some implementations include one or more processors of one or more computing devices, where the one or more processors are operable to execute instructions stored in associated memory, and where the instructions are configured to cause performance of any of the aforementioned methods. Some implementations also include one or more non-transitory computer readable storage media storing computer instructions executable by one or more processors to perform any of the aforementioned methods.

Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method for designing receiving coils of an inductive position sensor, the method comprising:
receiving input data indicating a shape of a target of the inductive position sensor;
identifying an overlapping region between the target and a transmitting coil of the inductive position sensor;
determining a shape of a receiving coil cell based on the identified overlapping region; and
generating a model of the receiving coils of the inductive position sensor based on the shape of the receiving coil cell.

2. The method of claim 1, further comprising generating a model of the target based on the input data.

3. The method of claim 1, wherein identifying the overlapping region comprises combining a model of the target and a model of the transmitting coil based on specification data of the inductive position sensor.

4. The method of claim 1, wherein the shape of the receiving coil cell is the same as a shape of the overlapping region.

5. The method of claim 1, further comprising determining a number of the receiving coil cells to be included in the model of the receiving coils.

6. The method of claim 5, further comprising determining a spacing between the number of the receiving coil cells.

7. The method of claim 5, further comprising:
receiving a benchmark waveform representing voltages as a function of a plurality of positions of the target;
generating a candidate model of the receiving coils, wherein the candidate model includes a plurality of the receiving coil cells arranged with a candidate spacing between one another;
simulating a movement of the target in the inductive position sensor with the candidate model;
recording voltages generated from the simulated movement of the target;
comparing the recorded voltages with the benchmark voltages; and
generating the model of the receiving coils based on the comparison between the recorded voltages with the benchmark voltages.

8. The method of claim 7, further comprising:
in response to the recorded voltages being the same as the benchmark voltages, setting the candidate spacing as a final spacing between the plurality of the receiving coil cells in the model of the receiving coils; and
in response to the recorded voltages being different from the benchmark voltages:
adjusting the candidate spacing to generate a new candidate model;
simulating a movement of the target in the inductive position sensor with the new candidate model;
recording new voltages generated from the simulated movement of the target in the inductive position sensor with the new candidate model;
comparing the recorded new voltages with the benchmark voltages; and
generating the model of the receiving coils based on the comparison between the recorded new voltages with the benchmark voltages.

9. The method of claim 1, further comprising:
generating printed circuit board (PCB) design data including the model of receiving coils and a model of the transmitting coil; and
sending the PCB design data to an apparatus configured to print the receiving coils and the transmitting coil on a PCB.

10. A system comprising:
a memory configured to store a set of instructions;
a processor configured to be in communication with the memory, the processor being configured to execute the set of instructions to:
receive input data indicating a shape of a target of an inductive position sensor;
identify an overlapping region between the target and a transmitting coil of the inductive position sensor;
determine a shape of a receiving coil cell based on the identified overlapping region; and
generate a model of receiving coils of the inductive position sensor based on the shape of the receiving coil cell.

11. The system of claim 10, wherein the processor is further configured to combine a model of the target and a model of the transmitting coil based on specification data of the inductive position sensor to identify the overlapping region.

12. The system of claim 10, wherein the shape of the receiving coil cell is the same as a shape of the overlapping region.

13. The system of claim 10, wherein the processor is configured to:
determine a number of the receiving coil cells to be included in the model of the receiving coils; and
determine a spacing between the number of the receiving coil cells.

14. The system of claim 10, wherein the processor is configured to:
receive a benchmark waveform representing voltages as a function of a plurality of positions of the target;
generate a candidate model of the receiving coils, wherein the candidate model includes a plurality of the receiving coil cells arranged with a candidate spacing between one another;
simulate a movement of the target in the inductive position sensor with the candidate model;
record voltages generated from the simulated movement of the target;
compare the recorded voltages with the benchmark voltages; and
generate the model of the receiving coils based on the comparison between the recorded voltages with the benchmark voltages.

15. The system of claim 14, wherein the processor is further configured to:
in response to the recorded voltages being the same as the benchmark voltages, set the candidate spacing as a final spacing between the plurality of the receiving coil cells in the model of the receiving coils; and
in response to the recorded voltages being different from the benchmark voltages:
adjust the candidate spacing to generate a new candidate model;
simulate a movement of the target in the inductive position sensor with the new candidate model;
record new voltages generated from the simulated movement of the target in the inductive position sensor with the new candidate model;
compare the recorded new voltages with the benchmark voltages; and
generate the model of the receiving coils based on the comparison between the recorded new voltages with the benchmark voltages.

16. The system of claim 10, wherein the processor is configured to:
generate printed circuit board (PCB) design data including the model of receiving coils and a model of the transmitting coil; and
send the PCB design data to an apparatus configured to print the receiving coils and the transmitting coil on a PCB.

17. A computer program product for designing receiving coils of an inductive position sensor, the computer program product comprising a computer readable storage medium having program instructions executable by a processor to:
receive input data indicating a shape of a target of the inductive position sensor;
identify an overlapping region between the target and a transmitting coil of the inductive position sensor;
determine a shape of a receiving coil cell based on the identified overlapping region; and
generate a model of the receiving coils of the inductive position sensor based on the shape of the receiving coil cell.

18. The computer program product of claim 17, wherein the shape of the receiving coil cell is the same as a shape of the overlapping region.

19. The computer program product of claim 17, wherein the program instructions are executable by a processor to:
receive a benchmark waveform representing voltages as a function of a plurality of positions of the target;
generate a candidate model of the receiving coils, wherein the candidate model includes a plurality of the receiving coil cells arranged with a candidate spacing between one another;
simulate a movement of the target in the inductive position sensor with the candidate model;
record voltages generated from the simulated movement of the target;
compare the recorded voltages with the benchmark voltages;
generate the model of the receiving coils based on the comparison between the recorded voltages with the benchmark voltages;
in response to the recorded voltages being the same as the benchmark voltages, set the candidate spacing as a final spacing between the plurality of the receiving coil cells in the model of the receiving coils; and
in response to the recorded voltages being different from the benchmark voltages:
adjust the candidate spacing to generate a new candidate model;
simulate a movement of the target in the inductive position sensor with the new candidate model;
record new voltages generated from the simulated movement of the target in the inductive position sensor with the new candidate model;
compare the recorded new voltages with the benchmark voltages; and
generate the model of the receiving coils based on the comparison between the recorded new voltages with the benchmark voltages.

20. The computer program product of claim 17, wherein the program instructions are executable by a processor to:
generate printed circuit board (PCB) design data including the model of receiving coils and a model of the transmitting coil; and
send the PCB design data to an apparatus configured to print the receiving coils and the transmitting coil on a PCB.
